(19) United States
(12) Patent Application Publication
(10) Pub. No.: US 2012/0142398 A1
(43) Pub. Date: Jun. 7, 2012

(54) WIRELESS COMMUNICATION MODULE AND GSM MULTIBAND WIRELESS COMMUNICATION MODULE

(75) Inventor: Hiroyuki Tamaoka, Tokyo (JP)

(73) Assignee: FURUKAWA ELECTRIC CO., LTD., Tokyo (JP)

(21) Appl. No.: 13/389,873

(22) PCT Filed: Mar. 3, 2010
(86) PCT No.: PCT/JP2010/053471

§ 371 Date: Feb. 10, 2012

(51) Int. Cl. H04B 1/50; H05K 7/00

(52) U.S. Cl. 455/557; 361/728

(57) ABSTRACT

A small wireless communication module and a GSM multiband wireless communication module that can achieve high radiation efficiency in predetermined frequency bands regardless of apparatus on which the module is mounted. The wireless communication module is obtained by integrating wireless communication units such as a radio frequency circuit and an antenna having communication functions to perform wireless communications into one module, and a module substrate is accommodated within a module casing. A planar conductor is placed on an outer circumferential surface of the module casing, and a grounding terminal and a driven element are provided on an end on a side of a connecting terminal.

### TECHNICAL FIELD

The present invention relates to a wireless communication module and a GSM multiband wireless communication module that perform wireless communications by being connected to a predetermined apparatus.

### BACKGROUND ART

In the development of portable communication terminals such as mobile phones, practical realization from the second generation (2G) to the third generation (3G) has proceeded to meet needs for high-speed communication, and the development of next generations is also advanced. While mobile phones of a WCDMA system as 3G have already become popular, a population coverage rate of a GSM system as 2G is still significantly high. Accordingly, portable communication terminals of 3G also need to have backward compatibility to be capable of handling the GSM system, and thus the mainstream of currently popular 3G portable communication terminals is those of GSM/WCDMA multiband specifications that can handle the both systems. In the GSM system, because frequency bands to be used vary according to communication areas, the communication terminals need to be multiband-architecture to handle any frequency band. Specifically, three frequency bands of a 900-MHz band, a 1800-MHz band, and a 1900-MHz band are used in the GSM system and the communication terminals need to be compatible with a GSM triple-band.

Furthermore, with the progress of the portable communication terminals, designing of a wireless communication section for performing wireless communications including radio frequency circuits, antennas and the like is becoming increasingly complicated and difficult, which requires large amounts of know-how and development resources, resulting in heavy burdens on developers. One of factors in complicating the designing of the wireless communication section is a fact that the area has become quite limited with demands for downsizing or increases in functions of the portable communication terminals. Furthermore, the wireless communication section is sensitive to environmental influences, such as greatly changing characteristics due to parts lay-out therearound and the like, and needs to be designed at each model.

As an example of improvement measures for designing of the wireless communication section, the development and practical realization to integrate the wireless communication section into a separate small module to reduce apparatus development costs has been advanced in the PHS system (Patent Document 1). FIG. 8 shows a wireless communication module described in Patent Document 1. A wireless communication module 900 shown in FIG. 8 has a dimension of about 42 mm×26 mm, and an antenna element 901 is located on a head of the wireless communication module 900. An apparatus 903 including the wireless communication module 900 having an independent wireless communication section, and a slot 902 on which the module can be mounted has been developed and already put to practical use.

Furthermore, as an example of wireless communication terminals other than mobile phones, Patent Document 2 describes an invention of a small module having a wireless communication unit mounted on a memory module that has a storage function. FIG. 9 shows a wireless communication module described in Patent Document 2. A wireless communication module 910 shown in FIG. 9 also includes an antenna element 911 placed on an end thereof, and then an RF module 912, a baseband LSI 913, and a memory element 914 are arranged in this order and mounted on a casing 915, which has a thickness of 3.5 mm or less. In this case, the module uses near field communication that is represented by Bluetooth® as a wireless communication unit and is adapted to removably connect to a host apparatus. In this manner, by incorporating a wireless communication module into apparatus that traditionally have no communication functions, apparatus that realize new values by utilizing communication functions have been increasingly proposed and turned into actual utilization.

### CITATION LIST

### Patent Literature

Patent Literature 1: Japanese Patent Application Laid-open No. 2008-118711
Patent Literature 2: Japanese Patent Application Laid-open No. 2001-143032

### SUMMARY OF INVENTION

### Technical Problem

To cause a wireless communication terminal of the 3G to easily handle also the GSM triple-band, a method is considered that enables to separate and modularize a wireless communication unit for the GSM triple-band and connect or disconnect the modularized wireless communication unit to or from a wireless communication terminal of 3G, like in the PHS system. When such a GSM-wireless communication module can be realized, this can lead to great reduction in development burdens not only in the development of 3 G communication terminals but also for future communication terminals such as the 3.9G in which MIMO (Multi-Input and Multi-Output) is installed.

However, in the GSM system, used frequencies include a 900-MHz band on a lower frequency side (a longer wavelength side) more than that in the PHS system in which used frequency thereof is a 1900-MHz band. Accordingly, it is quite difficult to realize a small wireless communication module that can also handle the 900-MHz band. While it is assumed that a wireless communication module needs to have a dimension of about 40×20 mm, a central wavelength of the 900-MHz band is about 333 mm and is much longer than the dimension. If an antenna used in such a long wavelength is greatly downsized, not only the bandwidth is forced to be narrowed or radiation efficiency is forced to be reduced but also it even becomes difficult to resonate.

In addition, to standardize GSM-compliant wireless communication modules, it is necessary to prevent wireless communication performance from depending on apparatus on which the wireless communication modules are mounted. If external influences cannot be reduced on the side of a wireless communication module, there arises a need to perform adjustment on the side of an apparatus on which the wireless communication module is mounted to minimize the dependence on the wireless communication module. As a result, an object of reducing the development burdens cannot be achieved.

The present invention has been achieved to solve the above problems, and an object of the present invention is to provide a small wireless communication module and a GSM multiband wireless communication module that can achieve high radiation efficiency in predetermined frequency bands regardless of apparatus on which the module is mounted.

### Solution to Problem

A first aspect of a wireless communication module according to the present invention provides a wireless communication module capable of being mounted on an apparatus that includes an apparatus substrate and an apparatus-side connecting terminal, the wireless communication module comprising: a module substrate that includes at least a module circuit having a wireless communication function, a module ground-plane (GND), and a connecting terminal capable of being connected to the apparatus-side connecting terminal, has the module circuit and the module GND placed on a surface or inside thereof, and has the connecting terminal placed on an end thereof to be exposed outside; a module casing that accommodates therein the module substrate except for the connecting terminal; a planar conductor that has a larger area than that of the module substrate, has one end to be connected to the module ground on a side of the connecting terminal to form a grounding terminal, is spread from the grounding terminal toward an opposite side to the connecting terminal, is folded back near an end of the module casing to surround at least the module substrate from upper and lower sides, and has the other end opened to form an open end; and a driven element that is connected to a feeding point provided in the module substrate to excite the planar conductor, wherein in a state where the wireless communication module is mounted on the apparatus and the connecting terminal is connected to the apparatus-side connecting terminal, the open end is located on an opposite side of the module substrate to the apparatus substrate.

Another aspect of the present invention provides the wireless communication module, wherein the planar conductor is placed within the module casing to cover an outer surface of the module substrate.

Another aspect of the present invention provides the wireless communication module, wherein the planar conductor is placed on an outer surface of the module casing.

Another aspect of the present invention provides the wireless communication module, wherein the driven element has a spring formed of a conductor, and the spring has one end that is connected to the feeding point provided in the module substrate on a side of the connecting terminal and the other end that feeds the planar conductor in a contact manner, thereby exciting the planar conductor.

Another aspect of the present invention provides the wireless communication module, wherein the driven element has a micro element formed of a conductor, and the micro element is connected to the feeding point provided in the module substrate on an opposite side to the connecting terminal to feed the planar conductor in a non-contact manner, thereby exciting the planar conductor.

Another aspect of the present invention provides the wireless communication module that further comprises a dielectrics that has a higher relative permittivity than that of a base material of the module substrate.

A first aspect of a GSM multiband wireless communication module according to the present invention provides a GSM multiband wireless communication module that is used in two or more GSM frequency bands and is mounted on an apparatus including an apparatus substrate and a predetermined slot to cause the apparatus to function as a mobile communication terminal, the GSM multiband wireless communication module comprising: a module substrate that includes at least a module circuit having a GSM wireless communication function, a module ground-plane, and a connecting terminal that is removably inserted into the slot and connected thereto, has the module circuit and the module ground-plane placed on a surface or inside thereof, and has the connecting terminal placed on an end thereof to be exposed outside; a module casing that accommodates therein the module substrate except for the connecting terminal; a planar conductor that has a larger area than that of the module substrate, has one end to be connected to the module ground-plane on a side of the connecting terminal to form a grounding terminal, is spread from the grounding terminal toward an opposite side to the connecting terminal, is folded back near an end of the module casing to surround at least the module substrate from upper and lower sides, and has the other end opened to form an open end; and a driven element that is connected to a feeding point provided in the module substrate to excite the planar conductor, wherein in a state where the GSM multiband wireless communication module is inserted into the slot and the connecting terminal is connected to the apparatus-side connecting terminal, the open end is located on an opposite side of the module substrate to the apparatus substrate, and the module ground-plane is connected to an apparatus ground-plane provided on the apparatus substrate through the connecting terminal, thereby causing the planar conductor to be an antenna element that functions in the two or more GSM frequency bands.

Another aspect of the present invention provides the GSM multiband wireless communication module, wherein a notch adjusted to obtain predetermined radiation performance in each of the two or more GSM frequency bands is formed in the planar conductor.

Another aspect of the present invention provides the GSM multiband wireless communication module, wherein the planar conductor is placed within the module casing to cover an outer surface of the module substrate.

Another aspect of the present invention provides the GSM multiband wireless communication module, wherein the planar conductor is placed on an outer surface of the module casing.

Another aspect of the present invention provides the GSM multiband wireless communication module, wherein the driven element has a spring formed of a conductor, and the spring has one end that is connected to the feeding point provided in the module substrate on a side of the connecting terminal and the other end that feeds the planar conductor in a contact manner, thereby exciting the planar conductor.

Another aspect of the present invention provides the GSM multiband wireless communication module, wherein the driven element has an electrically small element formed of a conductor, and the electrically small element is connected to the feeding point provided in the module substrate on an opposite side to the connecting terminal to feed the planar conductor in a non-contact manner, thereby exciting the planar conductor.

Another aspect of the present invention provides the GSM multiband wireless communication module, wherein the driven element further includes a dielectrics having a higher relative permittivity than that of a base material of the module substrate.

### Advantageous Effects of Invention

As described above, according to the present invention, an antenna element is formed of a planar conductor with a large area, thereby enabling to provide a small wireless communication module and a GSM multiband wireless communication module that can achieve high radiation efficiency in predetermined frequency bands regardless of apparatus on which the module is mounted.

### BRIEF DESCRIPTION OF DRAWINGS

FIG. 1 Perspective views and a cross-sectional view of a schematic configuration of a wireless communication module according to a first embodiment of the present invention.

FIG. 2 A perspective view of a detailed configuration of a module substrate according to the first embodiment.

FIG. 3 Perspective views of an apparatus that connects the wireless communication module.

FIG. 4 Perspective views of a schematic configuration of a wireless communication module according to a second embodiment.

FIG. 5 A perspective view showing a configuration of a module substrate to be used for a schematic configuration of a wireless communication module according to a third embodiment.

FIG. 6 Perspective views of a schematic configuration of a GSM multiband wireless communication module according to an embodiment of the present invention.

FIG. 7 A graph showing an example of antenna characteristics.

FIG. 8 A plan view showing a conventional wireless communication module.

FIG. 9 A plan view showing another conventional wireless communication module.

### DESCRIPTION OF EMBODIMENTS

A wireless communication module and a GSM multiband wireless communication modules according to preferred embodiments of the present invention will be explained in detail with reference to the accompanying drawings. Respective constituent elements having like functions are denoted by like reference numerals to simplify illustrations and explanations thereof.

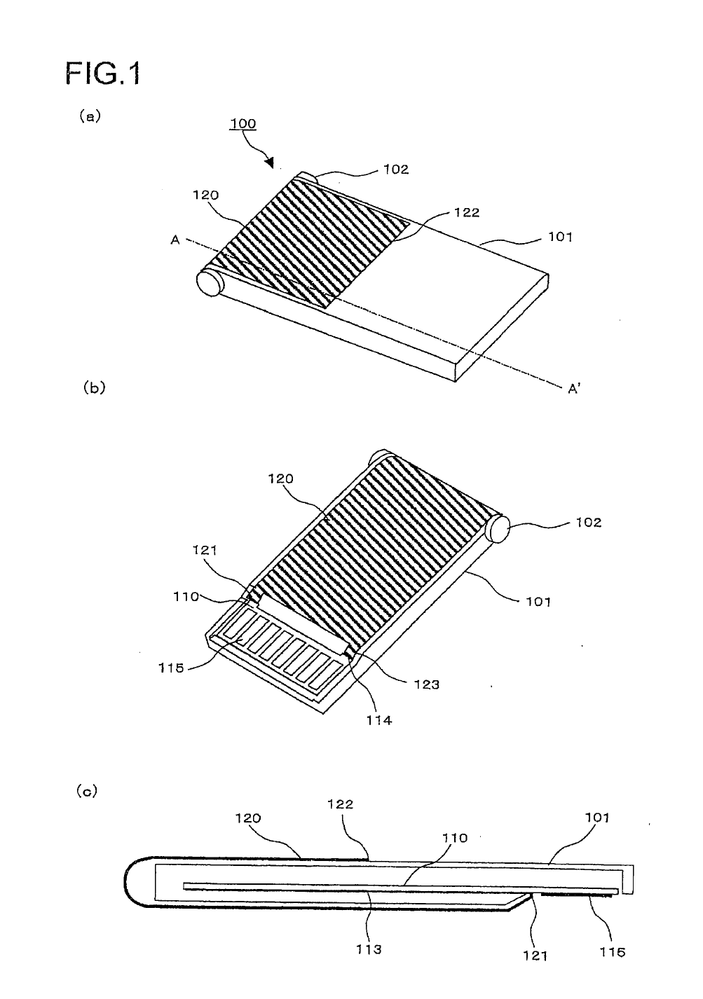

A wireless communication module according to a first embodiment of the present invention is explained with reference to FIG. 1. FIG. 1 shows a schematic configuration of a wireless communication module 100 according to the present embodiment, where FIG. 1(a) is a perspective view as viewed from a top surface, FIG. 1(b) is a perspective view as viewed from a bottom surface, and FIG. 1(c) is a cross-sectional view. The cross-sectional view shown in FIG. 1(c) is a view taken along a line AA′ in the perspective view shown in FIG. 1(a). The wireless communication module 100 is obtained by integrating a wireless communication unit including a radio frequency circuit, an antenna and the like, which have a communication function to perform wireless communications into one module. A module substrate 110 is accommodated within a module casing 101.

In the present embodiment, a planar conductor 120 is placed on an outer circumferential surface of the module casing 101. When the planar conductor 120 is placed on the outer circumference of the module casing 101, which is an outermost circumferential surface of the wireless communication module 100, in this way, an area of the planar conductor 120 can be maximized in the module.

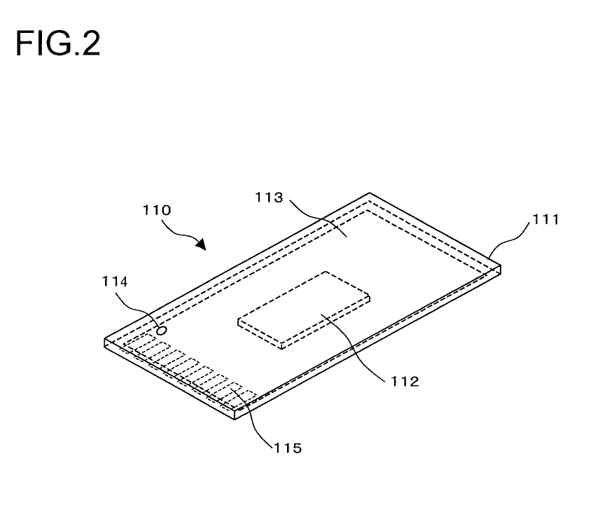

A detailed configuration of the module substrate 110 is shown in FIG. 2. FIG. 2 is a perspective view of a detailed configuration of the module substrate 110 as viewed from a top surface thereof, in which elements internally accommodated, a connecting terminal 115 placed on a bottom of the module substrate and the like, are shown by broken lines. The module substrate 110 accommodates a module circuit 112 that performs signal processing and the like required for wireless communications, a module ground-plane 113, and a feeding point 114 on a surface or inside of a base material 111 formed of a dielectrics.

In the following explanations, with respect to the outer circumferential surfaces of the module casing 101 and the module substrate 110, a surface on an upper side in the cross-sectional view shown in FIG. 1(c) is referred to as an upper surface, a surface on a lower side as a lower surface, a surface on a right side as a right side surface, and a surface on a left side as a left side surface. The module substrate 110 includes the connecting terminal 115 on the left side of the lower surface in addition to the above configuration. A wiring pattern and the like are properly routed between the module circuit 112 and the feeding point 114 or the connecting terminal 115, which are omitted in FIGS. 1 and 2.

The module casing 101 accommodates therein the module substrate 110 to isolate the elements other than the connecting terminal 115 from outside. A buffer material 102 is attached on an end of the module casing 101 opposite to the connecting terminal 115. The buffer material 102 is a portion that is held when the wireless communication module 100 is attached to or detached from an apparatus as a connection target and can be formed of a rubber material or the like.

The wireless communication module 100 is characterized by having an antenna formed by using the planar conductor 120. The planar conductor 120 has an area larger than the module casing 101 and is placed to cover the outer circumferential surface of the module casing 101. When the planar conductor 120 is placed in this way, the area can be increased up to about twice the area of the module casing 101. Accordingly, an antenna having satisfactory characteristics also in a low frequency of about 900 MHz can be formed of the planar conductor 120 without performing any excessive downsizing.

A driven element 123 that is connected to the feeding point 114 on the left side of the lower surface of the module substrate 110 on a side of the connecting terminal 115 and a grounding terminal 121 that is connected to the module ground-plane 113 are placed on an end of the planar conductor 120. The planar conductor 120 is spread along the lower surface of the module casing 101 from the grounding terminal 121 to right (to the opposite side of the connecting terminal 150) and folded back on the right side surface of the module casing 101 to be spread over the upper surface of the module casing 101. The other end of the planar conductor 120 is opened on the left side of the upper surface of the module casing 101 to form an open end 122. The area of the planar conductor 120 can be increased by placing the planar conductor 120 approximately in parallel with the both surfaces of the module casing 101 in this way.

The driven element 123 according to the present embodiment is placed on the side of the planar conductor 120 and placed on an end on the same side as the grounding terminal 121. In the present embodiment, the driven element 123 is brought into direct contact with the feeding point 114 to be fed. The driven element 123 has a configuration of a spring formed of a conductor to enhance contact with the feeding point 114. An end of the driven element 123 is connected to the planar conductor 120 and the other end is stably brought into contact with the feeding point 114 through spring force, thereby enabling to stably feed the planar conductor 120 and achieve excitation. While the driven element 123 has a leaf spring configuration in the present embodiment, the driven element 123 is not limited thereto and can be formed in a configuration of a coil spring, for example.

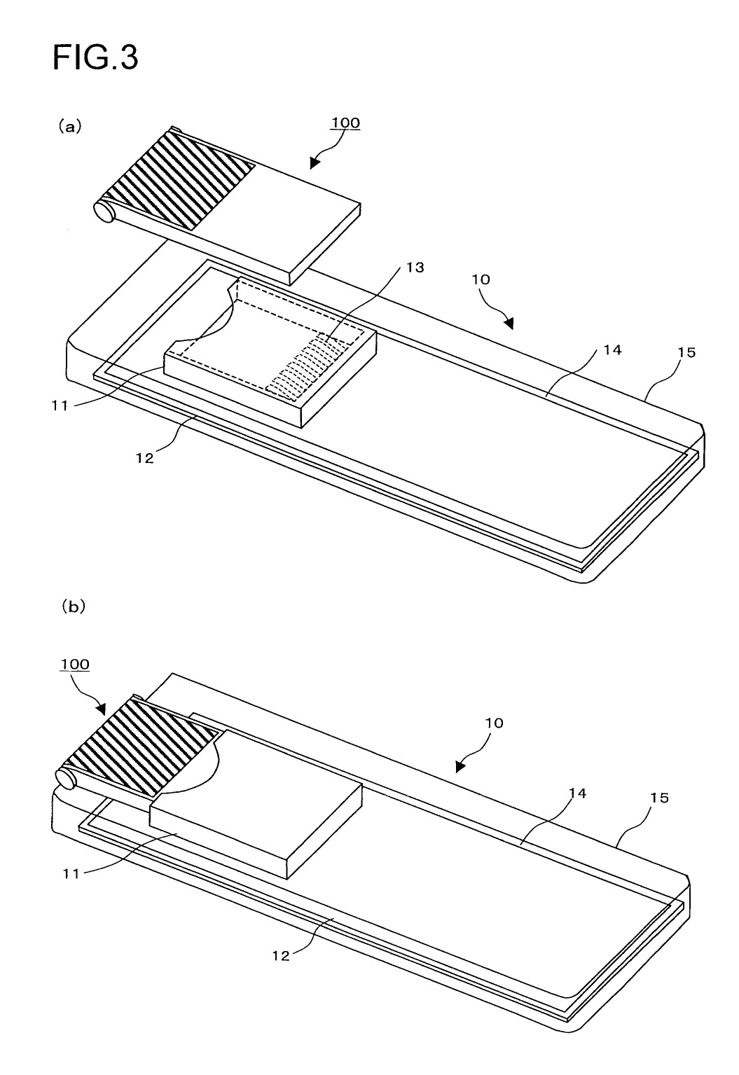

An apparatus including a predetermined connection receiving unit for connecting the wireless communication module 100 thus configured according to the present embodiment and mounts the wireless communication module 100 thereon to perform wireless communications is explained next. As the connection receiving unit, a slot that enables the wireless communication module 100 to be connected thereto by inserting the module from the side of the connecting terminal 115 can be used, for example. An example of an apparatus that can be connected to the wireless communication module 100 is shown in FIG. 3. FIG. 3 is perspective view showing states before and after the wireless communication module 100 is connected to an apparatus 10, where FIG. 3(a) shows a state before the wireless communication module 100 is connected thereto and FIG. 3(b) shows a state after the wireless communication module 100 is connected thereto.

The apparatus 10 has a slot 11 on an end of an apparatus casing 15, to which the wireless communication module 100 can be removably inserted and connected. Inside the apparatus casing 15, there is an apparatus substrate 12 having an apparatus-side connecting terminal 13 on an end on a side of the slot 11. In FIG. 3, the apparatus casing 15 is made transparent to show an inside thereof. An apparatus ground-plane 14 is provided on a surface of the apparatus substrate 12 where the slot 11 is placed (an upper surface in FIG. 3). The apparatus substrate 12 incorporates therein circuits that realize main functions of the apparatus and the like. The apparatus casing 15 isolates from outside the apparatus substrate 12 that is accommodated therein.

When the wireless communication module 100 is to be connected to the apparatus 10 having the configuration above described, the wireless communication module 100 is inserted into the slot 11 with the connecting terminal 115 facing the side of the apparatus substrate 12 and the open end 122 of the planar conductor 120 facing the opposite side. This causes the connecting terminal 115 of the wireless communication module 100 and the apparatus-side connecting terminal 13 to connect with each other. The apparatus is configured so that the module ground 113 and the apparatus ground-plane 14 are connected with each other when the connecting terminal 115 and the apparatus-side connecting terminal 13 are connected with each other. This causes the planar conductor 120 to be placed in parallel with the apparatus ground-plane 14 having a larger area and to function as an inverted-F antenna element having the grounding terminal 121 as a ground point by being fed from the driven element 114.

In the wireless communication module 100 according to the present embodiment, the outer surface of the module casing 101 is almost entirely used so that the planar conductor 120 with a large area can be placed thereon, thereby realizing resonance in a lower frequency band and avoiding reduction in the bandwidth and in the radiation efficiency due to downscaling. Further, the planar conductor 120 is folded back and placed to surround the upper and lower surfaces of the module casing 101, thereby realizing increase in frequency bands used. In an antenna operation using the planar conductor 120, a magnetic current near the open end 122 becomes a main radiation source and areas with high field intensities are concentrated in a portion of the module substrate 110 surrounded by the planar conductor 120. Because the areas with high electric field intensities are surrounded by the planar conductor 120, influences of the shape of the apparatus 10 on which the wireless communication module 100 is mounted, the internal configuration thereof and the like can be reduced, resulting in stable radiation characteristics.

The wireless communication module 100 according to the present embodiment can be connected not only to the portable terminals such as the mobile phones but also to various apparatus by forming a connection receiving unit (the slot 11) on the apparatus to provide a wireless communication function for the apparatus. Because the wireless communication module 100 is configured to be freely attached to or detached from the connection receiving unit, it is unnecessary that the wireless communication module 100 be prepared individually for each apparatus, and the wireless communication module 100 can be appropriately inserted to other apparatus.

Furthermore, when wireless communication terminals of the third generation, or the 3.9 or later generations are configured to have the slot 11 thereon, these wireless communication terminals can easily handle the GSM triple-band by using the wireless communication module 100 compliant with the GSM triple-band.

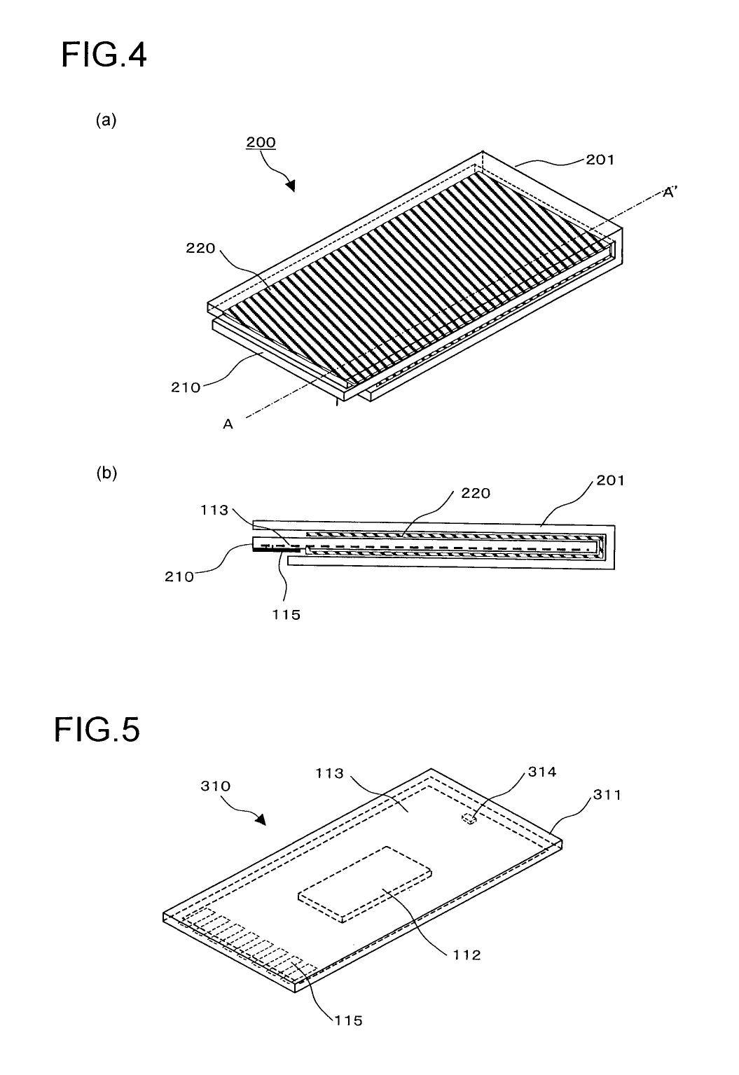

A wireless communication module according to a second embodiment of the present invention is explained with reference to FIG. 4. FIG. 4 has perspective and cross-sectional views showing a schematic configuration of a wireless communication module according to the present embodiment, where FIG. 4(a) is a perspective view as viewed from a top surface and FIG. 4(b) is a cross-sectional view. The cross-sectional view shown in FIG. 4(b) is a view taken from a line AA′ in the perspective view shown in FIG. 4(a). FIG. 4(a) is a perspective view in which a module casing 201 is made transparent to comprehensively show an inside of the module casing 201.

In a wireless communication module 200 according to the present embodiment, a planar conductor 220 is placed on an outer circumferential surface of a module substrate 210, and the module substrate 210 and the planar conductor 220 are integrally accommodated within the module casing 201. While the planar conductor 120 is spread on the outer circumference of the module casing 101 in the first embodiment described above, the planar conductor 220 is spread between the module substrate 210 and the module casing 201 in the present embodiment. This enables the planar conductor 220 to be protected by the module casing 201. Further, electromagnetic effects on the module substrate 210 exerted from outside are reduced by covering the module substrate 210 with the planar conductor 220. In this way, influences of the shape of the apparatus 10 on which the wireless communication module 200 is mounted, the internal configuration thereof and the like are reduced and stable radiation characteristics can be realized.

A wireless communication module according to a third embodiment of the present invention is explained with reference to FIG. 5. FIG. 5 is a perspective view showing a configuration of a module substrate 310 to be used for a wireless communication module according to the present embodiment. While in the wireless communication module 100, the driven element 123 connected to the planar conductor 120 is brought into direct contact with the feeding point 114 to feed power, it is also possible to feed the planar conductor by being capacitive-coupled with the driven element 123 in a non-contact manner. The wireless communication module according to the present embodiment has a configuration in which the planar conductor 220 is placed on an outer circumferential surface of the module substrate 310, like in the second embodiment, to capacitive-couple the planar conductor with a driven element in a non-contact manner to feed power.

On the module substrate 310, a feeding point that feeds the planar conductor 220 is placed on a right side surface opposite to the connecting terminal 115, and the planar conductor 220 is capacitive-coupled with a driven element 314 connected to the feeding point in a non-contact manner to be fed. The driven element 314 is placed a predetermined distance away from a portion of the planar conductor 220 spread on a lower surface of the module substrate 310 across a base material 311, thereby achieving capacitive coupling between the driven element 314 and the planar conductor 220.

The driven element 314 can be formed by using a electrically small conductor and the conductor can be also formed by being combined with a dielectrics having a higher relative permittivity than that of the base material 311. When the dielectric having a higher relative permittivity is placed between the conductor of the driven element 314 and the planar conductor 220, highly capacitive coupling therebetween can be achieved.

In the present embodiment, the frequency band can be expanded by using the driven element 314 that performs capacitive-coupling in a non-contact manner and feeding.

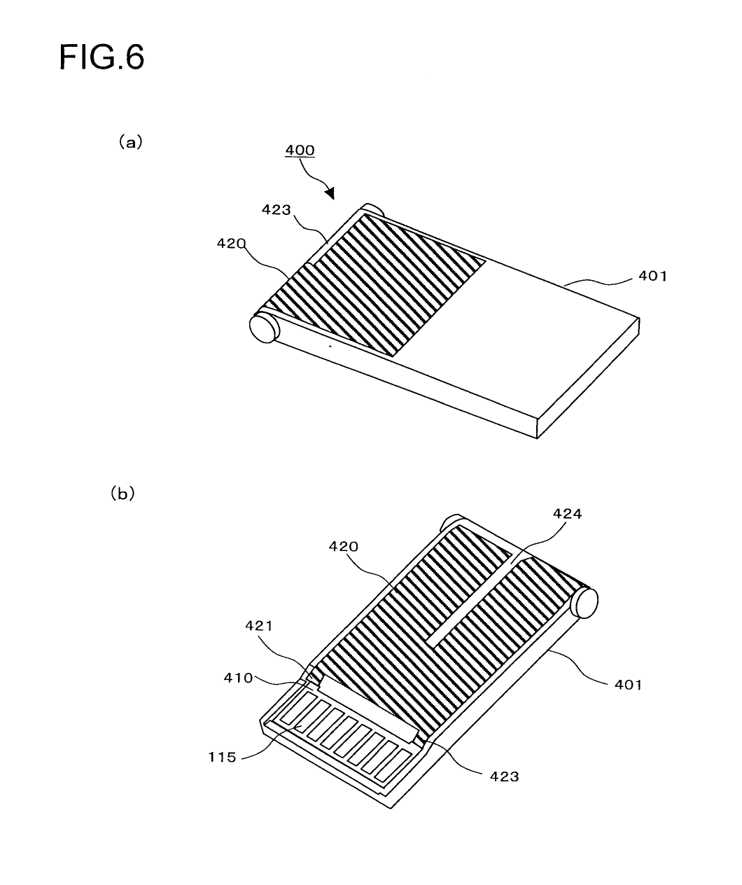

An embodiment of a GSM multiband wireless communication module of the present invention is explained below. The GSM multiband wireless communication module of the present invention is obtained by adapting the wireless communication module of the present invention to be compliant with the GSM multiband. The GSM multiband includes the three frequency bands, the 900-MHz band, the 1800-MHz band, and the 1900-MHz band, and the GSM multiband wireless communication module according to the present embodiment is adapted to be used in the GSM multiband. FIGS. 6(a) and 6(b) show perspective views of a GSM multiband wireless communication module 400 according to the present embodiment, as respectively viewed from a top surface and a bottom surface thereof.

In the GSM multiband wireless communication module 400, a module substrate 410 is accommodated in a module casing 401, and a planar conductor 420 is spread on an outer surface of the module casing 401 like in the wireless communication module 100. The module substrate 410 includes the module circuit 112, the module ground 113, and the feeding point 114 on a surface or inside thereof, and has the connecting terminal 115 on the left side of a lower surface thereof, like the module substrate 110. A grounding terminal 421 and a driven element 423 are placed on an end of the planar conductor 420 on a side of the connecting terminal 115.

In the GSM multiband wireless communication module 400 according to the present embodiment, a notch 424 is formed in the planar conductor 420 so that when the module 400 is inserted into the slot 11 of the apparatus 10 as shown in FIG. 3, for example, the planar conductor 420 operates as an antenna element compliant with the GSM multiband. The notch 424 is formed by cutting a portion of the planar conductor 420, and the placement, the shape and the like thereof are optimally determined to obtain satisfactory antenna characteristics in each of the three frequency bands used.

In the 900-MHz band having a lowest frequency (having a longest wavelength) in the frequency bands used for the GSM, a central wavelength is about 333 mm and even a quarter wavelength is about 83 mm. Accordingly, the GSM multiband wireless communication module 400 is required to reduce the size to about 40×20 mm. In such a small module, if a linear antenna is formed to include an antenna compliant with the 900-MHz band arranged in a width direction and folded back once, the antenna can ensure only a length of 40 mm at most and cannot achieve satisfactory antenna characteristics.

In contrast, when the planar conductor 420 is used, an antenna length up to 800 mm can be ensured on the both surfaces of the module casing 401 and, by appropriately forming the notch 424, satisfactory antenna characteristic for the used frequency band of 900 MHz can be realized. The placement and the shape of the notch 424 can be optimized to obtain the satisfactory antenna characteristics also for the 1800-MHz band and the 1900-MHz band.

When the GSM multiband wireless communication module 400 thus configured is inserted into the slot 11 of the apparatus 10 as shown in FIG. 3, the connecting terminal 115 and the apparatus-side connecting terminal 13 are connected with each other, thereby connecting the module ground 113 to the apparatus ground 14. When the module ground 113 is connected to the apparatus ground 14, the planar conductor 420 is placed in parallel with the apparatus ground 14 with a larger area and grounded, resulting in functioning as an antenna element compliant with the GSM multiband.

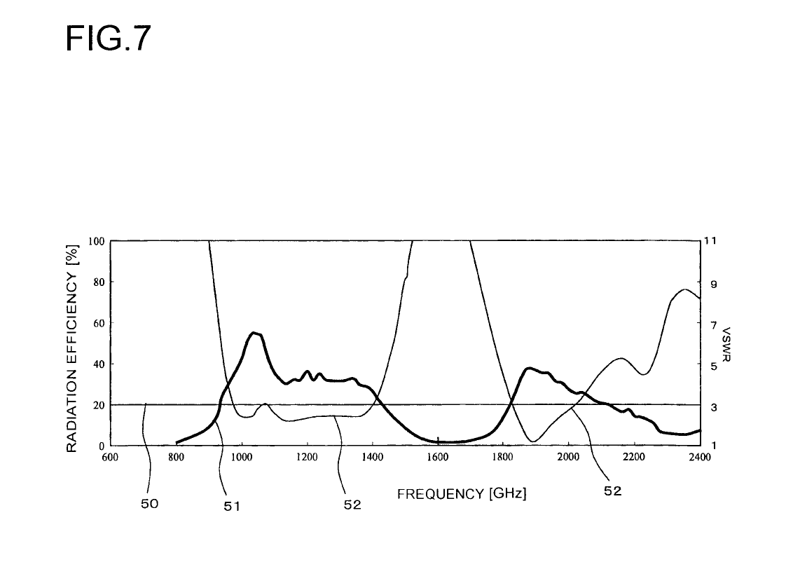

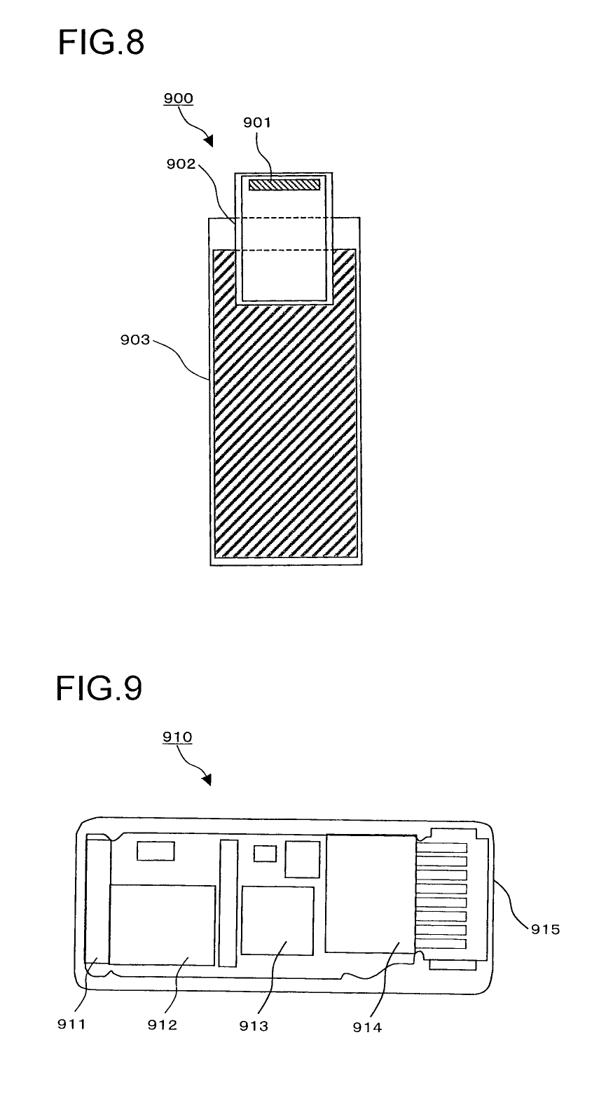

An example of the antenna characteristics of the GSM multiband wireless communication module 400 according to the present embodiment is explained with reference to FIG. 7. FIG. 7 is a graph showing an example of radiation efficiency and a VSWR (Voltage Standing Wave Ratio) obtained when the GSM multiband wireless communication module 400 is mounted on the apparatus 10. In FIG. 7, a 20% level of the radiation efficiency shown by a line 50 indicates maximum radiation efficiency in a conventional GSM-compliant antenna. The radiation efficiency and the VSWR are denoted by reference numerals 51 and 52, respectively. In a conventional GSM-compliant wireless portable terminal, a small antenna is mounted at a corner thereof and can realize radiation efficiency of only about 20% by using the antenna. In contrast, the GSM multiband wireless communication module 400 according to the present embodiment achieves high radiation efficiency near the frequency bands of the 900-MHz band, the 1800-MHz band, and the 1900-MHz band. While frequency bands with high radiation efficiency are slightly deviated from the desired frequency bands in FIG. 7, suitable radiation efficiency can be obtained by further adjustment.

Descriptions of the above embodiments are only examples of the wireless communication module and the GSM multiband wireless communication module according to the present invention, and the present invention is not limited thereto. As for detailed configurations and detailed operations of the wireless communication module and the GSM multiband wireless communication module according to the above embodiments, modifications can be appropriately made within the scope of the present invention.

### REFERENCE SIGNS LIST

10 Apparatus
11 Slot
12 Apparatus substrate
13 Apparatus-side connecting terminal
14 Apparatus ground-plane
15 Apparatus casing
100, 200, 900, 910 Wireless communication module
101, 201, 401 Module casing
102 Buffer material
110, 210, 310, 410 Module substrate
111, 311 Base material
112 Module circuit
113 Module ground-plane
114 Feeding point
115 Connecting terminal
120, 220, 420 Planar conductor
121, 421 Grounding terminal
122 Open end
123, 314, 423 Driven element
400 GSM multiband wireless communication module
424 Notch

1. A wireless communication module capable of being mounted on an apparatus that includes an apparatus substrate and an apparatus-side connecting terminal, the wireless communication module comprising:
a module substrate that includes at least a module circuit having a wireless communication function, a module ground-plane, and a connecting terminal capable of being connected to the apparatus-side connecting terminal, has the module circuit and the module ground-plane placed on a surface or inside thereof, and has the connecting terminal placed on an end thereof to be exposed outside;
a module casing that accommodates therein the module substrate except for the connecting terminal;
a planar conductor that has a larger area than that of the module substrate, has one end to be connected to the module ground on a side of the connecting terminal to form a grounding terminal, is spread from the grounding terminal toward an opposite side to the connecting terminal, is folded back near an end of the module casing to surround at least the module substrate from upper and lower sides, and has the other end opened to form an open end; and
a driven element that is connected to a feeding point provided in the module substrate to excite the planar conductor, wherein
in a state where the wireless communication module is mounted on the apparatus and the connecting terminal is connected to the apparatus-side connecting terminal, the open end is located on an opposite side of the module substrate to the apparatus substrate.

2. The wireless communication module according to claim 1, wherein the planar conductor is placed within the module casing to cover an outer surface of the module substrate.

3. The wireless communication module according to claim 1, wherein the planar conductor is placed on an outer surface of the module casing.

4. The wireless communication module according to any one of claims 1 to 3, wherein the driven element has a spring formed of a conductor, and the spring has one end that is connected to the feeding point provided in the module substrate on a side of the connecting terminal and the other end that feeds the planar conductor in a contact manner, thereby exciting the planar conductor.

5. The wireless communication module according to claim 2, wherein the driven element has a electrically small element formed of a conductor, and the electrically small element is connected to the feeding point provided in the module substrate on an opposite side to the connecting terminal to feed the planar conductor in a non-contact manner, thereby exciting the planar conductor.

6. The wireless communication module according to claim 5, further comprising a dielectrics that has a higher relative permittivity than that of a base material of the module substrate.

7. A GSM multiband wireless communication module that is used in two or more GSM frequency bands and is mounted on an apparatus including an apparatus substrate and a predetermined slot to cause the apparatus to function as a mobile communication terminal, the GSM multiband wireless communication module comprising:
a module substrate that includes at least a module circuit having a GSM wireless communication function, a module ground-plane, and a connecting terminal that is removably inserted into the slot and connected thereto, has the module circuit and the module ground-plane placed on a surface or inside thereof, and has the connecting terminal placed on an end thereof to be exposed outside;
a module casing that accommodates therein the module substrate except for the connecting terminal;
a planar conductor that has a larger area than that of the module substrate, has one end to be connected to the module ground on a side of the connecting terminal to form a grounding terminal, is spread from the grounding terminal toward an opposite side to the connecting terminal, is folded back near an end of the module casing to surround at least the module substrate from upper and lower sides, and has the other end opened to form an open end; and
a driven element that is connected to a feeding point provided in the module substrate to excite the planar conductor, wherein
in a state where the GSM multiband wireless communication module is inserted into the slot and the connecting terminal is connected to the apparatus-side connecting terminal, the open end is located on an opposite side of the module substrate to the apparatus substrate, and the module ground is connected to an apparatus ground-plane provided on the apparatus substrate through the connecting terminal, thereby causing the planar conductor to be an antenna element that functions in the two or more GSM frequency bands.

8. The GSM multiband wireless communication module according to claim 7, wherein a notch adjusted to obtain predetermined radiation characteristics in each of the two or more GSM frequency bands is formed in the planar conductor.

9. The GSM multiband wireless communication module according to claim 7 or 8, wherein the planar conductor is placed within the module casing to cover an outer surface of the module substrate.

10. The GSM multiband wireless communication module according to claim 7 or 8, wherein the planar conductor is placed on an outer surface of the module casing.

11. The GSM multiband wireless communication module according to claim 7 or 8, wherein the driven element has a spring formed of a conductor, and the spring has one end that is connected to the feeding point provided in the module substrate on a side of the connecting terminal and the other end that feeds the planar conductor in a contact manner, thereby exciting the planar conductor.

12. The GSM multiband wireless communication module according to claim 9, wherein the driven element has a micro element formed of a conductor, and the electrically small element is connected to the feeding point provided in the module substrate on an opposite side to the connecting terminal to feed the planar conductor in a non-contact manner, thereby exciting the planar conductor.

13. The GSM multiband wireless communication module according to claim 12, wherein the driven element further includes a dielectric having a higher relative permittivity than that of a base material of the module substrate.
